(19) United States
(12) Patent Application Publication
(10) Pub. No.: US 2012/0139066 A1
(43) Pub. Date: Jun. 7, 2012

(54) MEMS MICROPHONE

(75) Inventors: Chang Han JE, Daejeon (KR); Jaewoo Lee, Daejeon (KR); Woo Seok Yang, Daejeon (KR); Jongdae Kim, Daejeon (KR)

(73) Assignee: Electronics and telecommunications Research Institute, Daejeon (KR)

(21) Appl. No.: 13/252,733

(22) Filed: Oct. 4, 2011

(30) Foreign Application Priority Data
Dec. 3, 2010 (KR) 10-2010-0122738

(51) Int. Cl. H01L 29/84

(52) U.S. Cl. 257/416; 257/E29.324

(57) ABSTRACT

Disclosed is a micro electro mechanical system (MEMS) microphone including: a substrate; an acoustic chamber formed by processing the substrate; a lower electrode formed on the acoustic chamber and fixed to the substrate; a diaphragm formed over the lower electrode so as to be spaced apart from the lower electrode by a predetermined interval; and a diaphragm discharge hole formed at a central portion of the diaphragm. According to an exemplary embodiment of the present disclosure, attenuation generated by an air layer between the diaphragm and the lower electrode in a MEMS microphone may be effectively reduced, thereby making it possible to obtain high sensitivity characteristics and reduce a time and a cost required for removing a sacrificial layer between the diaphragm and the lower electrode.

### CROSS-REFERENCE TO RELATED APPLICATIONS

This application is based on and claims priority from Korean Patent Application No. 10-2010-0122738, filed on Dec. 3, 2010, with the Korean Intellectual Property Office, the present disclosure of which is incorporated herein in its entirety by reference.

### TECHNICAL FIELD

The present disclosure relates to a micro device using a micro electro mechanical system (MEMS) technology, and more particularly, to a capacitive MEMS microphone for removing attenuation by concentrated air on a central portion of a diaphragm.

### BACKGROUND

An acoustic sensor, that is, a microphone is a device converting an acoustic signal such as an audio into an electrical signal. This MEMS microphone may be divided into two types of MEMS microphones, that is, a capacitive MEMS microphone and a MEMS piezoelectric microphone. The capacitive MEMS microphone, which uses the principle of a condenser in which two electrodes face each other, is configured so that one electrode is fixed on a substrate and the other electrode is floated in the air to move to a vibration plate in response to sound pressure from the outside. In this configuration, when the sound pressure is applied from the outside, a diaphragm vibrates to change a clearance between two electrodes, which changes a capacitance and a current flows. The capacitive MEMS microphone may convert an acoustic signal into an electrical signal through the above-mentioned phenomenon. This capacitive MEMS microphone has excellent frequency characteristics and is stable. Therefore, most microphones of the related art have used the capacitive scheme.

FIGS. 1A and 1B are cross-sectional views of the capacitive MEMS microphone according to the related art.

The microphone according to the related art shown in FIG. 1A is configured to include a substrate 111, a lower electrode 121 formed on substrate 111, lower electrode discharge holes 122 formed in the lower electrode, a diaphragm 131, and a rear acoustic chamber 112. As shown in FIG. 1A, the microphone according to the related art uses a method of forming a large rear acoustic chamber 112 penetrating through substrate 111 by processing a rear surface of substrate 111 and forming a plurality of lower electrode discharge holes 122 in the lower electrode in order to reduce attenuation due to air 134 between diaphragm 131 and lower electrode 121. In this configuration, when the sound pressure is applied from the outside, edge portions of diaphragm 131 are fixed by supporters 133, such that a central portion thereof vibrates while vertically moving. In this case, the attenuation due to air 134 between diaphragm 131 and lower electrode 121 is the largest at the central portion. Further, at the edge portions of diaphragm 131, a side discharge hole 132 discharging the air to the edge side between diaphragm 131 and lower electrode 121 is formed, such that the attenuation is reduced. However, at the central portion, the air is not relatively discharged as compared to the edge side, such that the attenuation is increased, thereby causing deterioration in the sound pressure response characteristics.

A capacitive MEMS microphone shown in FIG. 1B is configured to include a lower electrode 121 formed on a substrate 111, lower electrode discharge holes 122 formed in lower electrode 121, a lower electrode supporter 123 supporting lower electrode 121, a diaphragm 131, and a rear acoustic chamber 112. As shown in FIG. 1B, the microphone according to the related art uses a method of forming rear acoustic chamber 112 in an inner portion of substrate 111 by processing a surface of substrate 111 and forming a plurality of lower electrode discharge holes 122 in lower electrode 121 in order to reduce attenuation due to air 134 between diaphragm 131 and lower electrode 121. However, even in this case, a method of discharging air at a central portion of diaphragm 131 is also not suggested, such that the attenuation due to the air at the central portion is increased, thereby causing deterioration in the sound pressure response characteristics.

As described above, the capacitive MEMS microphone according to the related art may deteriorate the sound pressure response characteristics due to the attenuation caused by the air concentrated on the central portion of the diaphragm.

Therefore, the demand for a capacitive MEMS microphone in which sound pressure characteristics are improved by removing attenuation due to air concentrated on a central portion of a diaphragm has been increased.

### SUMMARY

The present disclosure has been made in an effort to provide a microphone in which sound pressure response characteristics are improved by removing attenuation due to air concentrated on a central portion of a diaphragm in a capacitive MEMS microphone.

Further, the present disclosure has been made in an effort to provide a method capable of reducing a time and a cost by effectively removing a sacrificial layer between a diaphragm and a lower electrode in manufacturing a microphone. Other problems to be solved by the present disclosure can be understood by exemplary embodiments of the present disclosure.

An exemplary embodiment of the present disclosure provides a micro electro mechanical system (MEMS) microphone including: a substrate; an acoustic chamber formed by processing the substrate; a lower electrode formed on the acoustic chamber and fixed to the substrate; a diaphragm formed over the lower electrode so as to be spaced apart from the lower electrode by a predetermined interval; and a diaphragm discharge hole formed at a central portion of the diaphragm.

The acoustic chamber may be formed under the lower electrode to penetrate through the substrate by performing an etching process on a rear surface of the substrate.

The acoustic chamber may be formed to have a predetermined depth in the substrate by performing an etching process on a front surface of the substrate.

The lower electrode may include discharge holes formed therein to have a predetermined pattern.

The MEMS microphone may further include a lower electrode supporter formed between the lower electrode and a bottom of the acoustic chamber to prevent droop of the lower electrode.

The diaphragm may further include diaphragm supporters for connecting and attaching the diaphragm to the substrate.

The diaphragm supporters may be formed at all sides of the diaphragm.

The MEMS microphone may further include discharge holes formed adjacent to all sides of the diaphragm at which the diaphragm supporters are formed.

The diaphragm discharge hole may be formed of a combination of at least two discharge holes in the diaphragm.

A size, a shape, and a position of the diaphragm discharge hole may be controlled to control a degree of attenuation applied to the diaphragm.

The diaphragm may have an area that is the same as or larger than that of the lower electrode.

According to the exemplary embodiments of the present disclosure, the attenuation due to the air concentrated on the central portion of the diaphragm is removed through the central discharge hole formed in the diaphragm of the capacitive MEMS microphone, thereby making it possible to improve the frequency response characteristics.

In addition, according to the exemplary embodiments of the present disclosure, it is possible to reduce a time and a cost required for removing the sacrificial layer between the diaphragm and the lower electrode of the capacitive MEMS microphone.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A and 1B are cross-sectional views of the capacitive MEMS microphone according to the related art.

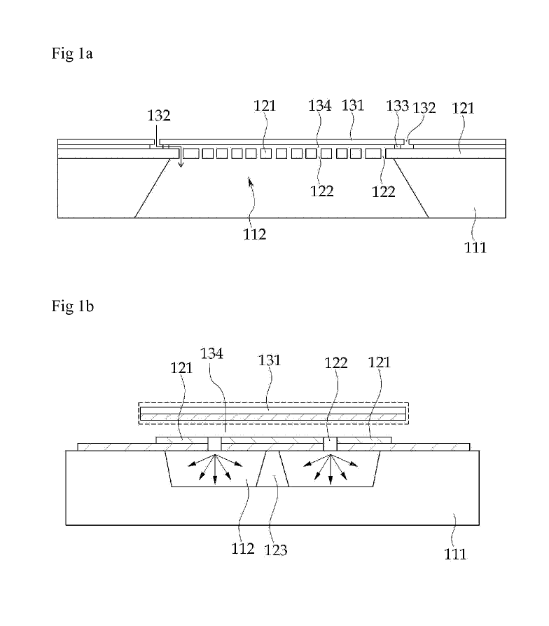

FIGS. 2A and 2B are concept views showing a configuration of a capacitive MEMS microphone including a diaphragm having a central discharge hole according to an exemplary embodiment of the present disclosure.

FIG. 3 is a plan view of the capacitive MEMS microphone shown in FIG. 2.

FIGS. 4A and 4B each are cross-sectional views of the capacitive MEMS microphone shown in FIGS. 2A and 2B.

FIGS. 5A and 5B are plan views showing a configuration a capacitive MEMS microphone including a diaphragm having a central discharge hole according to another exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings.

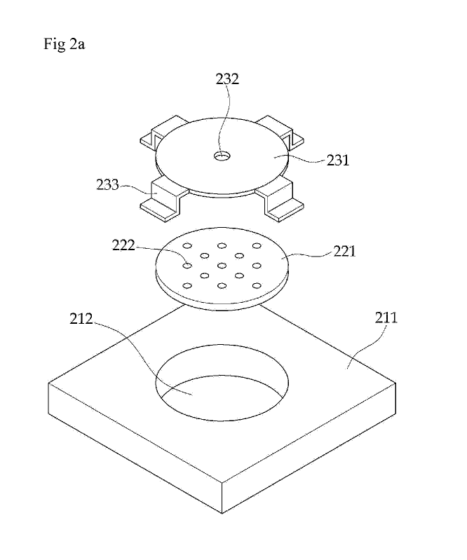

FIGS. 2A and 2B are concept views showing a configuration of a capacitive MEMS microphone including a diaphragm having a central discharge hole according to an exemplary embodiment of the present disclosure. As shown in FIGS. 2A and 2B, a capacitive MEMS microphone includes a substrate 211, an acoustic chamber 212 formed by processing the substrate, a lower electrode 221 formed on acoustic chamber 212, discharge holes 222 formed in a predetermined pattern in the lower electrode, a lower electrode supporter (not shown) supporting lower electrode 221, a diaphragm 231 spaced apart from lower electrode 221 by a predetermined interval to form an air layer, diaphragm supporters 233 connecting and attaching diaphragm 231 to substrate 211, and a diaphragm discharge hole 232 formed at a central portion of diaphragm 231.

Acoustic chamber 212 may be manufactured to have a shape in which it penetrates through the substrate by performing an etching process on a rear surface of substrate 211 as shown in FIG. 2A or be manufactured to have a concave shape in substrate 211 by performing an etching process on a front surface of substrate 211 under lower electrode 221 as shown in FIG. 2B.

As described above, in the microphone according to the related art, the diaphragm having a thin film shape in which a hole is not formed at the central portion thereof is used, such that the attenuation due to the air is concentrated on the central portion of the diaphragm, thereby causing deterioration in the sound pressure response characteristics. However, in the case of the capacitive MEMS microphone having the configuration shown in FIGS. 2A and 2B, diaphragm discharge hole 232 for discharging the air at the central portion of diaphragm 231 is formed, thereby making it possible to discharge the air at the central portion of diaphragm 231 at the time of vibration of the diaphragm by sound pressure. Therefore, attenuation due to the air concentrated on the central portion is removed, thereby making it possible to improve sound pressure response characteristics.

Diaphragm discharge hole 232 may have various sizes and shapes according to a size and a shape of diaphragm 231. In addition, a size, a shape, and a position of diaphragm discharge hole 232 are controlled, thereby making it possible to control a degree of the attenuation applied to the diaphragm.

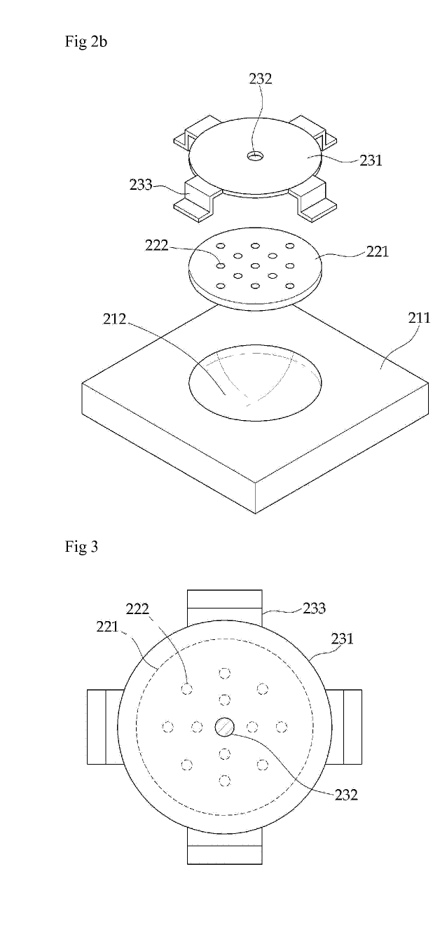

FIG. 3 is a plan view of the capacitive MEMS microphone shown in FIG. 2.

Referring to FIG. 3, diaphragm discharge hole 232 is formed at the central portion of diaphragm 231, and a plurality of lower electrode discharge holes 22 are formed in lower electrode 221 under vibration plate 231. In addition, diaphragm supporters 223 are formed at all sides of diaphragm 231, such that diaphragm 231 may be effectively connected to substrate 211.

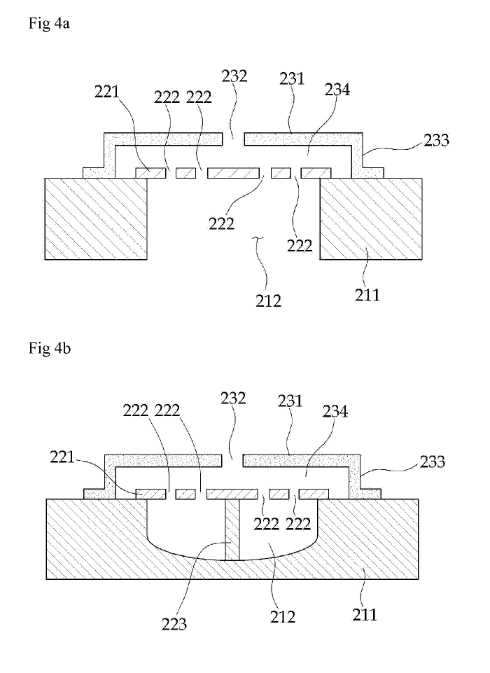

FIGS. 4A and 4B each are cross-sectional views of the capacitive MEMS microphone shown in FIGS. 2A and 2B.

Acoustic chamber 212 shown in FIG. 4A is manufactured to have a shape in which it penetrates through substrate 211 by performing an etching process on the rear surface of substrate 211. On the other hand, there is a difference in that acoustic chamber 212 shown in FIG. 4B is manufactured to have a shape in which it is formed in an inner portion of substrate 211 by performing an etching process on a front surface of substrate 211 by a predetermined depth under lower electrode 221. As shown in FIG. 4B, in order to support lower electrode 221, a lower electrode supporter 223 for preventing droop or deformation of lower electrode 221 may also be formed between a lower portion of lower electrode 221 and the etched portion of substrate 211.

Diaphragm 231 is positioned over lower portion 221, having a predetermined interval therebetween, and diaphragm 231 has an area that is the same as or larger than that of lower electrode 221. Diaphragm 231 is connected to substrate 211 and supported by diaphragm supporters 233 formed at edges thereof. In addition, edge sides of diaphragm 231 except for portions at which diaphragm supporters 223 are formed are opened to allow the air to be discharged, thereby making it possible to reduce the attenuation due to the air applied to the diaphragm in some degree.

Particularly, central portion of diaphragm 231 is provided with diaphragm discharge hole 232 in order to reduce the attenuation due to the air generated by an inter-electrode air layer 234 Diaphragm discharge hole 232 positioned at the central portion of the diaphragm serves to effectively reduce the attenuation due to the air intensively acting on the central portion of diaphragm 231 when diaphragm 231 vibrates by the sound pressure from the outside, thereby improving frequency response characteristics.

In addition, when a sacrificial layer between diaphragm 231 and lower electrode 221 is removed during a process of manufacturing the MEMS microphone, in the case of the capacitive MEMS microphone according to the related art, the sacrificial layer is removed through a side portion of diaphragm 231. Therefore, a time and a cost required for removing up to the air layer at the central portion of the diaphragm has increased. However, in the case of the capacitive MEMS microphone according to the exemplary embodiment of the present disclosure, the sacrificial layer at the central portion of diaphragm 231 may be more easily and rapidly removed through diaphragm discharge hole 232.

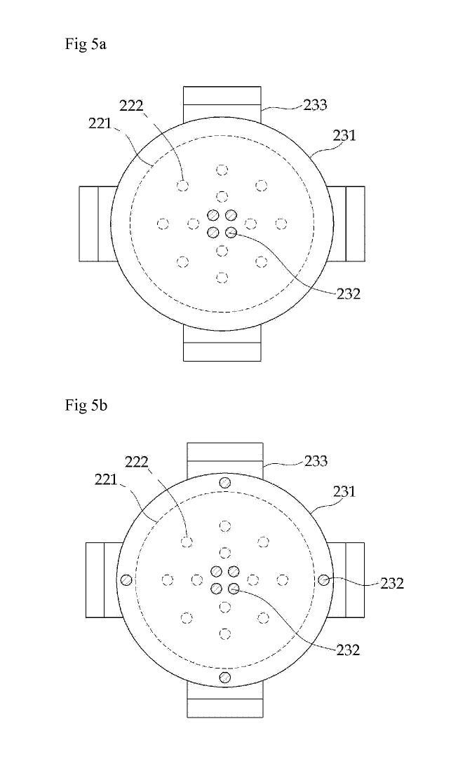

FIGS. 5A and 5B are plan views showing a configuration of a capacitive MEMS microphone including a diaphragm having a central discharge hole according to another exemplary embodiment of the present disclosure.

As shown in FIG. 5A, a diaphragm discharge hole 232 formed in a diaphragm 231 may be formed of a combination of a plurality of small holes rather than a single hole. In this case, as compared to a method in which a single hole is formed at the central portion of the diaphragm, the central portion having the largest displacement in the diaphragm may be used as an electrode, and an attenuation removal area by the discharge holes is increased to accomplish a higher attenuation removal effect, thereby making it possible to raise sensitivity of the MEMS microphone.

In addition, as shown in FIG. 5B, discharge holes 231 are not only formed at the central portion of diaphragm 231 but are also formed at portions at which the attenuation due to the air is higher, as compared to surrounding portions, such as portions adjacent to all sides of diaphragm 231 connected to diaphragm supporters 233 to reduce the attenuation, thereby making it possible to raise the sensitivity of the MEMS microphone.

As described above, according to the related art, the diaphragm is manufactured to have a thin film shape in which it does not include the hole, such that when the diaphragm vibrates by the sound pressure from the outside, the attenuation due to the air is concentrated on the central portion of the diaphragm, thereby causing deterioration in the sound pressure response characteristics. On the other hand, according to the exemplary embodiment of the present disclosure, the discharge hole is formed at the central portion of the diaphragm to remove the attenuation at the central portion of the diaphragm, thereby making it possible to improve the sound pressure response characteristics.

Further, in manufacturing the MEMS microphone, during a process of removing the sacrificial layer for forming a clearance between the lower electrode and the diaphragm, the sacrificial layer may be removed through the discharge hole at the central portion of the diaphragm as well as the side thereof, thereby making it possible to reduce a time and a cost.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A micro electro mechanical system (MEMS) microphone, comprising:
a substrate;
an acoustic chamber formed by processing the substrate;
a lower electrode formed on the acoustic chamber and fixed to the substrate;
a diaphragm formed over the lower electrode so as to be spaced apart from the lower electrode by a predetermined interval; and
a diaphragm discharge hole formed at a central portion of the diaphragm.

2. The MEMS microphone of claim 1, wherein the acoustic chamber is formed under the lower electrode to penetrate through the substrate by performing an etching process on a rear surface of the substrate.

3. The MEMS microphone of claim 1, wherein the acoustic chamber is formed to have a predetermined depth in the substrate by performing an etching process on a front surface of the substrate.

4. The MEMS microphone of claim 1, wherein the lower electrode includes discharge holes formed therein to have a predetermined pattern.

5. The MEMS microphone of claim 1, further comprising a lower electrode supporter formed between the lower electrode and a bottom of the acoustic chamber to prevent droop of the lower electrode.

6. The MEMS microphone of claim 1, wherein the diaphragm further includes diaphragm supporters for connecting and attaching the diaphragm to the substrate.

7. The MEMS microphone of claim 6, wherein the diaphragm supporters are formed at all sides of the diaphragm.

8. The MEMS microphone of claim 7, further comprising discharge holes formed adjacent to all sides of the diaphragm at which the diaphragm supporters are formed.

9. The MEMS microphone of claim 1, wherein the diaphragm discharge hole is formed of a combination of at least two discharge holes in the diaphragm.

10. The MEMS microphone of claim 1, wherein a size, a shape, and a position of the diaphragm discharge hole are controlled to control a degree of attenuation applied to the diaphragm.

11. The MEMS microphone of claim 1, wherein the diaphragm is the same as or larger than the lower electrode.
